(19) United States
(12) Patent Application Publication
(10) Pub. No.: US 2026/0255762 A1
(43) Pub. Date: Aug. 27, 2026

(54) LIGHT-EMITTING STRUCTURE, BACKLIGHT SOURCE AND DISPLAY APPARATUS

(71) Applicants: Hefei BOE Ruisheng Technology Co., Ltd., Hefei (Anhui) (CN); BOE TECHNOLOGY GROUP CO.,LTD., Beijing (CN)

(72) Inventors: Xiuxiu FANG, Beijing (CN); Lili JIA, Beijing (CN); Yutao HAO, Beijing (CN); Ying CHEN, Beijing (CN); Pei QIN, Beijing (CN); Xueqiao LI, Beijing (CN); Shanwei YANG, Beijing (CN); Jie GAO, Beijing (CN); Haiyang JIN, Beijing (CN)

(73) Assignees: Hefei BOE Ruisheng Technology Co., Ltd., Hefei (Anhui) (CN); BOE TECHNOLOGY GROUP CO.,LTD., Beijing (CN)

(21) Appl. No.: 18/994,225

(22) PCT Filed: May 31, 2024
(86) PCT No.: PCT/CN2024/096692

§ 371 Date: Jan. 14, 2025

(30) Foreign Application Priority Data
Jun. 29, 2023 (CN) 202310786990.5

(51) Int. Cl. H10H 29/853; H10H 29/855

(52) U.S. Cl. CPC H10H 29/853; H10H 29/855

(57) ABSTRACT

A light-emitting structure, a backlight source and a display apparatus are provided. The light-emitting structure includes a plurality of light emitting units located on a substrate and at least one light transmitting protection structure. Each light transmitting protection structure wraps one light emitting unit. An outer surface of the light transmitting protection structure includes a first portion and a second portion. A boundary position between the first portion and the second portion includes a first position that is farthest from the substrate in the light transmitting protection structure. A recessed portion includes a second position that is closest to the substrate in the first portion. A thickness of the light transmitting protection structure at the first position is H, a maximum thickness of the light emitting unit in a first direction perpendicular to the substrate is h, and H and h satisfy: 1<H/h<17.

The present application claims priority of the Chinese Patent Application No. 202310786990.5, filed on Jun. 29, 2023, the disclosure of which is incorporated herein its entirety as part of the present application.

### TECHNICAL FIELD

Embodiments of the present disclosure relate to a light-emitting structure, a backlight source and a display apparatus.

### BACKGROUND

Compared with traditional LED backlights, a direct-lit submillimeter light emitting diode (Mini LED) backlight can achieve more partitions thereby realizing high-definition, high-brightness and refined picture display. As a result, Mini LEDs are increasingly developed in the display field, especially in the television (TV) field, and are favored by more and more consumers.

### SUMMARY

Embodiments of the disclosure provide a light-emitting structure, a backlight source and a display apparatus. The light-emitting structure including: a substrate; a plurality of light emitting units, located on the substrate; and at least one light transmitting protection structure, configured to wrap at least one light emitting unit, wherein each light transmitting protection structure wraps one light emitting unit, an outer surface of the light transmitting protection structure comprises a first portion and a second portion surrounding the first portion, a boundary position between the first portion and the second portion comprises a first position that is farthest from the substrate in the light transmitting protection structure, the first portion comprises a recessed portion bent to a side close to the light emitting unit, the recessed portion comprises a second position that is closest to the substrate in the first portion, a thickness of the light transmitting protection structure at the first position is H, a maximum thickness of the light emitting unit in a first direction perpendicular to the substrate is h, and H and h satisfy a relationship: 1<H/h<17.

For example, according to an embodiment of the present disclosure, in a second direction parallel to the substrate, a distance between the first position and the second position is W, a size of the light emitting unit in the second direction is L, a largest size of the light transmitting protection structure in the second direction is D, and W. L and D satisfy a relationship: L/2<W<D/2.

For example, according to an embodiment of the present disclosure, an orthographic projection of the second position on the substrate is located within an orthographic projection of the light emitting unit on the substrate.

For example, according to an embodiment of the present disclosure, wherein the orthographic projection of the light emitting unit on the substrate has a first shape, a smallest distance between the second position and a straight line passing through a light emitting center of the light emitting unit and perpendicular to the substrate is greater than or equal to 0, and less than or equal to half of a size of the first shape.

For example, according to an embodiment of the present disclosure, a difference between H and a thickness of the light transmitting protection structure at the second position is Hm, and Hm/H<0.5.

For example, according to an embodiment of the present disclosure, a portion of the light transmitting protection structure with a thickness of H/2 has a size D′ in the second direction, and D′ and L satisfy a relationship: 3.5≤D′/L≤12.5.

For example, according to an embodiment of the present disclosure, D and L satisfy a relationship: 3≤D/L≤13.5.

For example, according to an embodiment of the present disclosure, the light emitting unit comprises a light emitting diode chip and the outer surface of the light transmitting protection structure covering the light emitting unit comprises a free-form curved surface.

For example, according to an embodiment of the present disclosure, the outer surface of the light transmitting protection structure from the second position to the first position comprises at least a section of a curved surface and/or a section of a planar surface.

For example, according to an embodiment of the present disclosure, the at least one light transmitting protection structure comprises a plurality of light transmitting protection structures, and each of at least some light emitting units of the plurality of light emitting units is wrapped by one light transmitting protection structure; and the substrate comprises a first area and a second area located on at least one side of the first area, the at least some light emitting units comprise a first light emitting unit located in the first area and a second light emitting unit located in the second area, the plurality of light transmitting protection structures comprise a first light transmitting protection structure wrapping the first light emitting unit and a second light transmitting protection structure wrapping the second light emitting unit, a straight line passing through a light emitting center of the first light emitting unit and perpendicular to the substrate passes through the second position of the first light transmitting protection structure, an orthographic projection of the second light emitting unit on the substrate has a second shape and a smallest distance between the second position and a straight line passing through a light emitting center of the second light emitting unit and perpendicular to the substrate is greater than 0, and less than or equal to half of a size of the second shape.

For example, according to an embodiment of the present disclosure, a shape of an orthographic projection of the at least one light emitting unit on the substrate comprises a rectangular, two adjacent sides of the rectangular extend in the second direction and a third direction respectively; and the light transmitting protection structure comprises one second position and a plurality of first positions, and the plurality of first positions surround the second position, a ratio of a distance between the second position and the first position in the second direction to a distance between the second position and the first position in the third direction is in a range from 0.8 to 1.2, and a ratio of distances between different first positions and the substrate is in a range from 0.8 to 1.2.

For example, according to an embodiment of the present disclosure, distances between the plurality of first positions and the substrate are all the same.

For example, according to an embodiment of the present disclosure, the plurality of first locations are connected in a clockwise direction to form a circular shape or an elliptical shape.

For example, according to an embodiment of the present disclosure, Hm satisfies: 0 mm<Hm≤1.2 mm.

For example, according to an embodiment of the present disclosure, H satisfies: 0.5 mm≤H≤2mm.

For example, according to an embodiment of the present disclosure, D satisfies: 4 mm≤D≤10 mm.

For example, according to an embodiment of the present disclosure, the light-emitting structure further including: a reflective layer, located on a side of the substrate provided with the plurality of light emitting units, wherein the reflective layer comprises a plurality of openings, the plurality of openings are disposed in one-to-one correspondence with the plurality of light emitting units, a size of at least one opening is D0, and D0 and D satisfy a relationship: 1.2≤D0/D≤1.5.

For example, according to an embodiment of the present disclosure, a material of the light transmitting protection structure comprises organic silica gel, a refractive index of the light transmitting protection structure is in a range from 1.3 to 1.7 and a transmissivity of the light transmitting protection structure is greater than 80%.

For example, according to an embodiment of the present disclosure, an emission wavelength of the light emitting unit is in a range from 430 nanometers to 480 nanometers and the light transmitting protection structure comprises an inorganic light emitting material.

Another embodiment of the disclosure provides a backlight source, including the light-emitting structure according to any items as mentioned above.

Another embodiment of the disclosure provides a display apparatus, including the light-emitting structure according to any items as mentioned above.

### BRIEF DESCRIPTION OF DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a partial cross-sectional structure diagram of a light-emitting structure.

FIG. 2 is a partial cross-sectional structure diagram of a light-emitting structure provided according to an embodiment of the present disclosure.

FIG. 3 is a planar view illustrating a light emitting unit and a light transmitting protection structure wrapping the light emitting unit in the light-emitting structure shown in FIG. 2.

FIG. 4 is a schematic diagram illustrating light-emitting intensity distribution in different configurations of a light emitting unit.

FIG. 5 is a structure diagram illustrating light transmitting protection structures at the second position with different thicknesses.

FIG. 6 is a light pattern curve of the light emitted from the light transmitting protection structures with different thicknesses shown in FIG. 5.

FIG. 7 is a planar structure of a light-emitting structure in another example according to an embodiment of the present disclosure.

FIG. 8 is a partial cross-sectional structure diagram taken along the line AA′ shown in FIG. 7.

FIG. 9 is a partial structure diagram of a light-emitting structure in another example according to an embodiment of the present disclosure.

FIG. 10 is a partial cross-sectional structure diagram of a backlight source according to another embodiment of the present disclosure.

FIG. 11 is a partial cross-sectional structure diagram of a display apparatus according to another embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise specified, the technical terms or scientific terms used in the disclosure shall have normal meanings understood by those skilled in the art. The words “first”, “second” and the like used in the disclosure do not indicate the sequence, the number or the importance but are only used for distinguishing different components. The word “comprise”, “include” or the like only indicates that an element or a component before the word contains elements or components listed after the word and equivalents thereof, not excluding other elements or components. As used in embodiments of the present disclosure, the features “parallel”, “perpendicular”, and “identical” include the features “parallel”, “perpendicular”, and “identical,” etc. in the strict sense, as well as “approximately parallel”, “approximately perpendicular”, and “approximately identical,” etc., which include a certain amount of error, are indicated to be within a range of acceptable deviations for a particular value as determined by a person of ordinary skill in the art, taking into account the measurement and the error associated with the measurement of the particular quantity (e.g., the limitation of the measurement system). For example, “substantially” can mean within one or more standard deviations, or within 10% or 5% of the stated value. Where the quantity of a component is not specifically indicated in the following embodiments of the present disclosure, it is meant that the component may be one or more, or may be understood to be at least one. “At least one” means one or more, and “a plurality of” means at least two.

A direct-lit backlight source is provided with a plurality of light emitting diodes (LEDs), such as a plurality of mini light-emitting diodes (Mini LEDs), through the light mixing of the light rays emitted by adjacent LEDs, the uniform display of the overall picture is achieved. The display effect of a display apparatus including a direct-lit backlight source is related not only to the optical distance (OD) in the backlight source and the pitch between adjacent LEDs, but also closely related to the emitted light pattern of the LEDs.

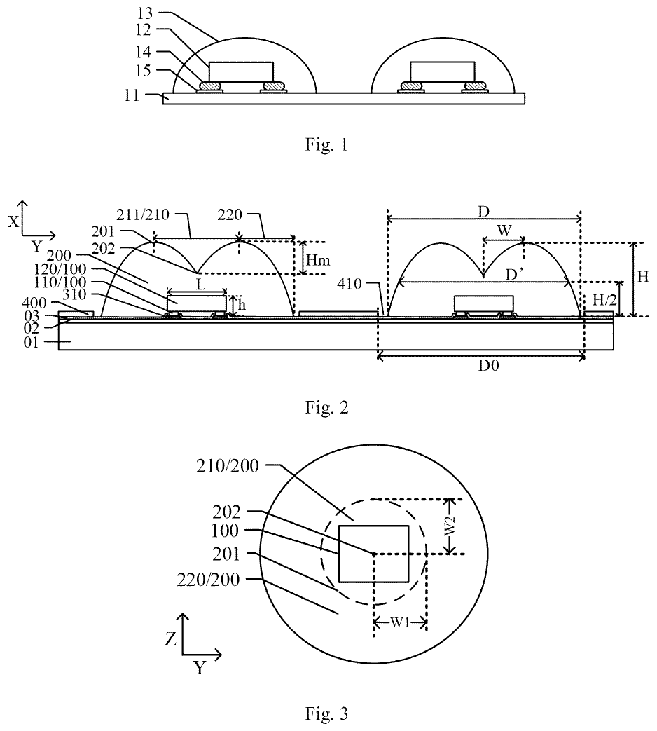

FIG. 1 is a partial cross-sectional structure diagram of a light-emitting structure. As shown in FIG. 1, during the fabrication process of a backlight source using Mini LEDs, the Mini LEDs 12 are soldered onto a substrate 11 through die bonding. For example, the Mini LEDs 12 include solder metal 14, for example, pins, and the pins are connected to the pads 15 on the substrate 11. In order to prevent the Mini LED chips from being exposed to the air and damaged by dirt and other contaminants, silica gel 13 is usually disposed on the surface of each Mini LED with a convex shape or roughly in a round dome shape. Since the silica gel has a certain refractive index, such as the refractive index of 1.5, which is greater than the refractive index of air, when the light emitted by Mini LEDs is refracted as it travels from the silica gel to air or other media, which changes the secondary light pattern of the light emitted by LED when it is emitted from silica gel.

In studies, the inventors of the present application have found that: in backlight designs of TV, under a certain optical distance (OD), the cost can be controlled by increasing the pitch between adjacent LEDs. Under a certain pitch, the thickness of a backlight module can be reduced by reducing the OD. Under some combinations of OD and pitch, the situation where the areas above the LEDs are bright while the areas between adjacent LEDs are dark will occur. As a result, there will be a display problem that the entire backlight picture will have bright and dark stripes and it will be difficult to achieve a uniform picture. Through analysis of the secondary light pattern of the light from the LEDs, it can be known that a light intensity of the LED at intermediate angles is not low enough.

Embodiments of the present disclosure provide a light-emitting structure, a backlight source and a display apparatus. The light-emitting structure includes a substrate, a plurality of light emitting units located on the substrate and at least one light transmitting protection structure, the at least one light transmitting protection structure is configured to wrap at least one light emitting unit. Each light transmitting protection structure wraps one light emitting unit. An outer surface of the light transmitting protection structure includes a first portion and a second portion surrounding the first portion. A boundary position between the first portion and the second portion includes a first position that is farthest from the substrate in the light transmitting protection structure. The first portion includes a recessed portion bent toward a side of the light emitting unit. The recessed portion includes a second position that is closest to the substrate in the first portion. A thickness of the light transmitting protection structure at the first position is H, a maximum thickness of the light emitting unit in a first direction perpendicular to the substrate is h, and Hand h satisfy a relationship: 1<H/h<17.

The light-emitting structure provided in the present disclosure, by setting a shape of the light transmitting protection structure wrapping the light emitting unit to include a recessed portion and by setting a relationship between the maximum thickness of the light transmitting protection structure and the maximum thickness of the light emitting unit, is conducive to achieving a specific secondary light pattern design for the light emitting unit, reducing the brightness right above the light emitting unit, decreasing the brightness difference between the area above the light emitting unit and the area between adjacent light emitting units, and realizing a uniform picture display.

The light-emitting structure, the backlight source and the display apparatus provided by the embodiments of the present disclosure will be described below with reference to the accompanying drawings.

FIG. 2 is a partial cross-sectional structure diagram of a light-emitting structure provided according to an embodiment of the present disclosure. FIG. 3 is a planar view illustrating a light emitting unit and a light transmitting protection structure wrapping the light emitting unit in the light-emitting structure shown in FIG. 2. As shown in FIG. 2, the light-emitting structure includes a substrate 01, a plurality of light emitting units 100 located on the substrate 01 and at least one light transmitting protection structure 200, and the at least one light transmitting protection structure 200 is configured to wrap at least one light emitting unit 100. FIG. 2 schematically shows two light emitting units 100 arranged in a Y direction, but not limited thereto, the light-emitting structure may include more light emitting units arranged in the Y direction.

For example, as shown in FIG. 2, the substrate 01 may be a printed circuit board (a PCB board) or may be made of glass, plastic, polyimide, polymethyl methacrylate or the like with circuits fabricated on them.

For example, as shown in FIG. 2, a buffer layer 02 is disposed on the substrate 01. For example, pads 310 are disposed on a side of the buffer layer 02 away from the substrate 01, the light emitting unit 100 includes pins 110 and a light emitting body 120, the pins 110 of the light emitting unit 100 are electrically connected to the pads 310. For example, a passivation layer (PVX) 03 is disposed on a side of the buffer layer 02 away from the substrate 01. For example, a material of the passivation layer 03 includes an insulating material, the passivation layer 03 includes openings exposing the pads 310 to enable the pins 110 of the light emitting units 100 to be electrically connected to the pads 310 exposed by the passivation layer 03.

As shown in FIG. 2, each light transmitting protection structure 200 wraps one light emitting unit 100. For example, the light transmitting protection structure 200 may wrap the portion of the light-emitting unit 100 other than a surface where the pin 110 and the pad 310 are connected electrically, to package and protect the unpackaged light-emitting unit. For example, the light transmitting protection structure 200 is in direct contact with the light-emitting unit 100, e.g., the surface of the light-emitting unit 100 away from the substrate 01 and the side surface of the light-emitting unit 100 are in direct contact with the light transmitting protection structure 200. For example, there may be no gap between the light transmitting protection structure 200 and the light-emitting unit 100 to avoid the reflection of light between the light-emitting unit 100 and the light transmitting protection structure 200. For example, the light transmitting protection structure 200 may be in contact with a surface on a side of the passivation layer 03 away from the substrate 01. For example, a surface on a side of the light transmitting protection structure 200 closest to the substrate 01 may be the surface where the light transmitting protection structure 200 is in contact with the passivation layer 03. Of course, embodiments of the present disclosure are not limited to this, other film layers may be disposed on the side of the passivation layer away from the substrate and the light transmitting protection structure may be in contact with the surface on the side of the other film layers that is away from the substrate. For example, light emitted from the light emitting unit 100 is refracted by the light transmitting protection structure 200 and then exit. A shape of the light transmitting protection structure 200 can determine the secondary light pattern of the light emitting unit 100.

As shown in FIG. 2, the outer surface of the light transmitting protection structure 200 may include a first portion 210 and a second portion 220 surrounding the first portion 210. For example, the first portion 210 and the second portion 220 may form a structure that is integrally provided. For example, a geometric center of an orthographic projection of the light transmitting protection structure 200 on the substrate 01 may be located within an orthographic projection of the first portion 210 on the substrate 01. For example, a shape of the orthographic projection of the first portion 210 on the substrate 01 may have a circular shape or an elliptical shape and a shape of the orthographic projection of the second portion 220 on the substrate 01 may have a ring shape, such as a circular ring shape or an elliptical ring shape. For example, the ring-shaped orthographic projection of the second portion 220 on the substrate 01 may be a shape with a uniform ring width, but not limited thereto. According to the product requirements, the ring width of the ring-shaped orthographic projection of the second portion on the substrate may be relatively large at some locations and relatively small at some other locations.

As shown in FIGS. 2 and 3, a boundary position between the first portion 210 and the second portion 220 includes a first position 201 that is farthest from the substrate 01 in the light transmitting protection structure 200. For example, the boundary positions between the first portion 210 and the second portion 220 may be a circle of first locations 201. For example, the first position 201 is the position in the first portion 210 with the farthest distance from the substrate 01, and the first position 201 is also the position in the second portion 220 with the farthest distance from the substrate 01. For example, the position in the second portion 220 that is at the smallest distance from the substrate 01 is the location of the edge of the light transmitting protection structure 200. For example, the light transmitting protection structure 200 includes a circle of convex structures, the circle of convex structures includes a circle of highest points. For example, the circle of highest points includes a plurality of first positions 201.

In some examples, as shown in FIG. 2 and FIG. 3, the light transmitting protection structure 200 includes one second position 202 and a plurality of first positions 201 surrounding the second position 202, and a ratio of the distances between different first positions 201 and the substrate 01 is in a range from 0.8 to 1.2. For example, different first positions 201 may be different points, connecting lines of all the first positions 201 in a clockwise direction form a circle of the first positions 201. For example, a ratio of the distances between different first positions 201 and the substrate 01 in a range from 0.9 to 1.1.

In some examples, as shown in FIG. 2 and FIG. 3, distances between different first positions 201 and the substrate 01 are all the same, which facilitates fabrication of the light transmitting protection structure and enables the light transmitting protection structure to make the same change to the secondary light pattern of the light emitted from the light emitting unit in at least some directions, for example, in two directions.

In some examples, as shown in FIGS. 2 and 3, connecting lines of the plurality of first positions 201 in a clockwise direction form a circular shape or an elliptical shape.

As shown in FIG. 2, the first portion 210 includes a recessed portion 211 bent to a side close to the light emitting unit 100. The recessed portion 211 includes a second position 202 that is closest to the substrate 01 in the first portion 201. A thickness of the light transmitting protection structure 200 at the first position 201 is H, a maximum thickness of the light emitting unit 100 in a first direction perpendicular to the substrate 01, such as an X direction, is h, and Hand h satisfy a relationship: 1<H/h<17. For example, H and h satisfy a relationship: 2<H/h<10. For example, the above-described thickness of the light transmitting protection structure 200 at a first position 201 may refer to a distance between the first position 201 and a surface of the light transmitting protection structure 200 that is closest to the substrate 01, i.e. the surface of the light transmitting protection structure 200 that is in contact with the passivation layer 03 as shown in FIG. 2. It can be understood that there is a distance between the second position 202 and the surface of the light emitting unit 100 away from the substrate 01, i.e. a distance between the second position 202 and the substrate 01 is greater than a distance between the surface of the light emitting unit 100 away from the substrate 01 and the substrate 01.

In the optical structure provided in the present disclosure, the light transmitting protection structure wrapping a light emitting unit serves as a secondary optical light distribution lens of the light emitting unit, by setting the shape of the light transmitting protection structure to include a recessed portion, a relationship between the maximum thickness of the light transmitting protection structure and the maximum thickness of the light emitting unit is set at the same time, is conducive to achieving a specific secondary light pattern design for the light emitting unit, reducing the brightness right above the light emitting unit, decreasing the brightness difference between the area above the light emitting unit and the area between adjacent light emitting units, and realizing a uniform picture display.

FIG. 2 schematically shows that each light emitting unit 100 has a light transmitting protection structure 200 including a recessed portion disposed on its side away from the substrate 01, but not limited thereto, at least one light emitting unit 100 (e.g., a light emitting unit located in a certain area of the light-emitting structure) may have a light transmitting protection structure without recessed portion disposed on its side away from the substrate 01, for example, the shape of the light transmitting protection structure may be approximately dome-shaped of the silica gel 13 shown in FIG. 1. For example, the light-emitting structure includes a plurality of light transmitting protection structures, the plurality of light transmitting protection structures including a first light transmitting protection substructure and a second light transmitting protection substructure, the first light transmitting protection substructure includes the above-described recessed portion and the second light transmitting protection substructure includes a round dome shape. The first light transmitting protection substructures are distributed in a first sub-area of the light-emitting structure and the second light transmitting protection substructures are distributed in a second sub-area of the light-emitting structure. For example, the first sub-area may be a central area including the geometric center of the substrate, while the second sub-area is an area surrounding the first sub-area. Alternately, the second sub-area may be a central area including the geometric center of the substrate, while the first sub-area is an area surrounding the second sub-area.

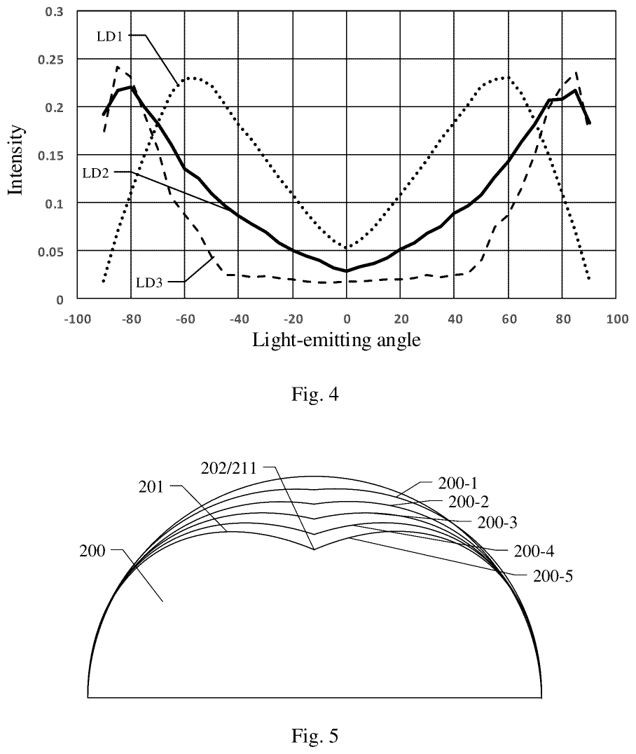

FIG. 4 is a schematic diagram illustrating light-emitting intensity distribution in different configurations of a light emitting unit. As shown in FIG. 4, the abscissa represents light-emitting angles of the light emitting unit, 0° represents the right center of the light emitting unit, and among the light emitted from the light emitting unit, the light-emitting angle in the direction toward the negative pole of the two pins is negative, while the light-emitting angle in the direction toward the positive pole of the two pins is positive; the ordinate represents normalized light-emitting intensity of the light emitting unit at the corresponding angle.

For example, as shown in FIG. 4, LD1 represents a light-emitting intensity distribution of a light emitting unit in the light-emitting structure shown in FIG. 2 without being wrapped by one light transmitting protection structure, LD2 represents a light-emitting intensity distribution of a light emitting unit in the light-emitting structure shown in FIG. 2 wrapped by one light transmitting protection structure having the round dome shape shown in FIG. 1, and LD3 represents a light-emitting intensity distribution of a light emitting unit in the light-emitting structure shown in FIG. 2 wrapped by the light transmitting protection structure 200 shown in FIG. 2.

For example, as shown in FIG. 4, the light-emitting surface of a light emitting unit 100 may be provided with a dimming structure, for example, a reflective film, to reduce the light-emitting intensity directly above the light emitting unit 100. For example, the light-emitting intensity at the light emitting angle of 0 degree is lower than the light-emitting intensity at the light emitting angle of 70 degrees in the light emitting unit 100. For example, all of the light-emitting intensity distributions illustrated by LD1, LD2 and LD3 have batwing light distribution characteristics. For example, the batwing light distribution characteristics are defined as that the optical axis passing through the geometric center of the light-emitting unit 100 is taken as 0 degree, and within the angles where the absolute value of the light distribution angle is greater than 0 degree, there is a light intensity distribution with a light intensity higher than that at 0 degree.

For example, as shown in FIG. 4, the light intensities of LD3 within the range of ±70 degrees are lower than the light intensities of LD1 and LD2 within the same light emitting angle range.

Compared with the situation where no light transmitting protection structure is disposed or the light transmitting protection structure wrapping a light emitting unit is set to have the round dome shape shown in FIG. 1, the optical structure provided in the present disclosure can further reduced the light-emitting intensity at the intermediate angles of the light emitting unit by setting a recessed portion in the first portion facing directly to the light emitting unit and by setting the relationship between the thickness of the light emitting unit and the thickness of the light transmitting protection structure. It is beneficial for reducing the light-emitting intensity at the intermediate angles of the light-emitting unit, such as reducing the light-emitting intensity within ±50 degrees of the exiting light rays emitted by the light emitting unit after passing through the light transmitting protection structure. Thereby, it can reduce the difference in light-emitting intensity between the area directly above light emitting unit and the area between adjacent light emitting units, solve the problem of bright and dark stripes that may occur when the light-emitting structure is used for display and improve the uniformity of light emission of the optical structure so as to achieve a uniform picture display.

For example, as shown in FIG. 2, H and h satisfy a relationship: 2≤H/h≤5. For example, H and h satisfy a relationship: 3<H/h≤7. For example, H and h satisfy a relationship: 4<H/h≤6. For example, H and h satisfy a relationship: 3.5<H/h≤8.

For example, as shown in FIG. 2, in the present disclosure, the maximum thickness h of a light emitting unit 100 may refer to a size including the light emitting body 120 and the pins 110 in the direction perpendicular to the planar where the substrate is located. Of course, the present disclosure is not limited to this, and the maximum thickness h of a light emitting unit 100 may also refer to the part of a light emitting unit excluding the pins 110, for example, the maximum thickness of the light emitting body.

For example, as shown in FIG. 2, the thickness h of a light emitting unit 100 may be a value not greater than 2 millimeters (mm), for example, 1 mm, 0.75 mm, 0.6 mm, 0.15 mm or 0.1 mm. For example, the thickness h of a light emitting unit 100 may be in a range from 70 mm to 180 mm.

In some examples, as shown in FIG. 2, the maximum thickness H of a light transmitting protection structure 200 satisfies: 0.5 mm≤H≤2 mm. For example, H satisfies: 0.6 mm≤H≤1.5 mm. For example, H satisfies: 0.7 mm≤H≤1.8 mm. For example, H satisfies: 1 mm≤H≤1.2 mm. For example, H satisfies: 0.8 mm≤H≤1.7 mm.

In some examples, as shown in FIG. 2, a difference between H and a thickness of the light transmitting protection structure 200 at the second position 202 is Hm and Hm/H<0.5.

For example, as shown in FIG. 2, the distance between a planar where the second position 202 is located (a planar perpendicular to the X direction) and a planar where a first position 201 is located (a planar perpendicular to the X direction) may be Hm. For example, Hm/H<0.48. For example, Hm/H<0.45. For example, Hm/H<0.4. For example, Hm/H<0.35. For example, Hm/H<0.3.

In some examples, as shown in FIG. 2, Hm satisfies: 0 mm<Hm≤1.2 mm. For example, 0.1 mm≤Hm≤0.5 mm.

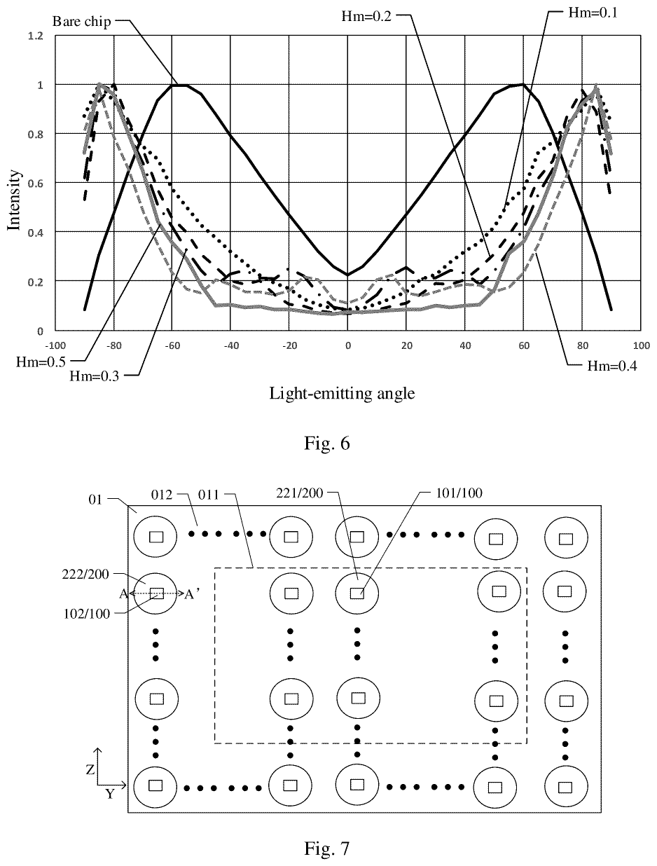

FIG. 5 is a structure diagram illustrating light transmitting protection structures at the second position with different thicknesses. FIG. 6 is a light pattern curve of the light emitted from the light transmitting protection structures with different thicknesses shown in FIG. 5.

For example, as shown in FIG. 2, FIG. 5 and FIG. 6, the light-emitting intensity of the exiting light rays at 0° from a light emitting unit 100 without a light transmitting protection structure 200(e.g. a bare chip) disposed on the light emitting side is greater than the light-emitting intensity of the exiting light rays at 0° from a light emitting unit 100 with a light transmitting protection structure 200 disposed on the light emitting side. For example, compared with the situation where the light emitting side of the light emitting unit 100 is not provided with the light transmitting protection structure, by setting a light transmitting protection structure 200 with a recessed portion 211 on the light emitting side of the light emitting unit 100, it is possible to reduce the brightness directly above the light emitting unit while expanding the angle of the position where the light-emitting intensity of the light emitted from the light transmitting protection structure 200 reaches its maximum by at least 10 degrees, thereby increasing the light intensity in the area between adjacent light-emitting units. For example, by setting a light transmitting protection structure 200 with a recessed portion 211 on the light emitting side of the light emitting unit 100, it is possible to reduce the brightness directly above the light emitting unit while expanding the angle of the position where the light-emitting intensity of the light emitted from the light transmitting protection structure 200 reaches its maximum by at least 15 degrees. For example, by setting a light transmitting protection structure 200 with a recessed portion 211 on the light emitting side of the light emitting unit 100, it is possible to reduce the brightness directly above the light emitting unit while expanding the angle of the position where the light-emitting intensity of the light emitted from the light transmitting protection structure 200 reaches its maximum by at least 20 degrees.

For example, as shown in FIG. 5 and FIG. 6, a difference in height Hm between the the first position 201 and the second position 202 in a light transmitting protection structure 200-1 is 0.1 mm, a difference in height Hm between the first position 201 and the second position 202 in a light transmitting protection structure 200-2 is 0.2 mm, a difference in height Hm between the first position 201 and the second position 202 in a light transmitting protection structure 200-3 is 0.3 mm, a difference in height Hm between the the first position 201 and the second position 202 in a light transmitting protection structure 200-4 is 0.4 mm, and a difference in height Hm between the first position 201 and the second position 202 in a light transmitting protection structure 200-5 is 0.5 mm. For example, the light-emitting intensity of exiting light rays at 0° from the light transmitting protection structure 200-5 is the least.

In some examples, as shown in FIG. 2, the outer surface of a light transmitting protection structure 200 covering the light emitting unit 100 includes a free-form curved surface.

In some examples, as shown in FIG. 2, the outer surface of the light transmitting protection structure 200 from the second position 202 to the first position 201 includes at least a section of a curved surface and/or a section of a planar surface. For example, the surface of the light transmitting protection structure 200 between the second position 202 and the first position 201 may be an annular curved surface. For example, the distances between the surface from the second position 202 to the first position 201 and the substrate 01 gradually increases.

For example, FIG. 2 schematically shows a section line taken by surface between the first position 201 and the second position 202 taken along the XY planar is a curve that bends to a side away from the substrate 01, but not limited thereto. For example, the section line taken through the surface between the first position and the second position taken along the XY planar may be a straight line, a fold line, a curve that bends to a side close to the substrate, etc., as can be configured according to practical light pattern requirements.

For example, FIG. 2 schematically shows that there is one peak (a first position 201) between the second position 202 and the edge of the light transmitting protection structure 200, but not limited thereto. There may also be two or more peaks between the second position and the edge of the light transmitting protection structure; among the plurality of peaks, the peak that is farthest from the substrate is the peak where the first position is located, or if the distances between the plurality of peaks and the substrate are all equal, the peak among the plurality of wave peaks that is closest to the center of the light transmitting protection structure is the peak where the first position is located.

For example, as shown in FIG. 2, the straight line through the second position 202 and perpendicular to the substrate 01 is taken as the central axis of the light transmitting protection structure 200 and the cross section of the light transmitting protection structure 200 taken along the XY planar is symmetrical about the central axis.

For example, as shown in FIG. 2, the second position 202 may be a point in the surface of the light transmitting protection structure 200, for example, the lowest point of the recessed portion 211. But not limited thereto, the second position may also be a planar, for example, the area of the planar is very small, for example, it can be less than 10% of the area of the light emitting unit.

In some examples, as shown in FIGS. 2 and 3, an orthographic projection of the second position 202 on the substrate 01 is located within an orthographic projection of the light emitting unit 100 on the substrate 01. By setting the orthographic projection of the second position of the light transmitting protection structure wrapping at least part of the light emitting unit on the substrate within the orthographic projection of the light emitting unit on the substrate, it is beneficial to perform roughly symmetrical modulation on the light emitted from at least part of the light transmitting protection structure.

In some examples, as shown in FIGS. 2 and 3, the orthographic projection of the light emitting unit 100 on the substrate 01 has a first shape, a smallest distance between the second position 202 a straight line passing through the light emitting center of the light emitting unit 100 and perpendicular to the substrate 01 is greater than or equal to 0 and less than or equal to half of a size of the first shape. For example, the size of the above-described first shape may be a size in the Y direction or a size in a Z direction, and the size may be a size in the extending direction of a line connecting the second position and the straight line through the light emitting center of the light emitting unit. For example, if the above-described first shape is a polygon, the size of the first shape is the length of a diagonal line or any side of the polygon; if the above-described first shape is a circle, the size of the first shape is the diameter of the circle; or if the above-described first shape is an ellipse, the size of the first shape is the major axis or minor axis of the ellipse.

For example, as shown in FIGS. 2 and 3, the straight line passing through the light emitting center of the light emitting unit 100 and perpendicular to the substrate 01 passes through the second position 202. For example, the light emitting center of the light emitting unit 100 may be the center of the light-emitting surface of the light emitting unit 100. For example, the optical axis of the light emitting unit 100 that is perpendicular to the substrate 01 passes through the light emitting center of the light emitting unit 100 and the second position 202 of the light transmitting protection structure 200.

By setting the second position of the light transmitting protection structure to be directly opposite to the light emitting center of the light emitting unit, it is beneficial to perform basically completely symmetrical modulation on the light emitted from the light transmitting protection structure.

In some examples, as shown in FIG. 2, in a second direction parallel to the substrate 01, for example, in the Y direction, a distance between the first position 201 and a second position 202 is W, a size of the light emitting unit 100 in the second direction is L, a largest size of the light transmitting protection structure 200 in the second direction is D, and W, L and D satisfy a relationship: L/2<W<D/2.

By setting a relationship among the size of a light emitting unit in a direction parallel to the substrate, and by setting the distance in the direction parallel to the substrate between the highest point and the lowest point of the first portion of the light transmitting protection structure and the size of the light transmitting protection structure in the direction parallel to the substrate, the light pattern of the light emitted through the light transmitting protection structure from the light emitting unit can be modulated, it is beneficial for reducing the light-emitting intensity within ±50 degrees of the exiting light rays emitted by the light emitting unit after passing through the light transmitting protection structure. Thereby, it can reduce the difference in light-emitting intensity between the area directly above light emitting unit and the area between adjacent light emitting units, solve the problem of bright and dark stripes that may occur when the light-emitting structure is used for display and improve the uniformity of light emission of the optical structure so as to achieve a uniform picture display.

For example, as shown in FIG. 2, W, L and D satisfy a relationship: 0.4*L<W<0.45*D.

In some examples, as shown in FIG. 2, D and L satisfy a relationship: 3≤D/L≤13.5. By setting the largest value of D/L to be not greater than 8, the reflective sheet is enabled to have an area as large as possible to retains a certain reflection ratio; and by setting the smallest value of D/L to be not less than 3, the effect of light homogenization can be improved as much as possible.

For example, as shown in FIG. 2, D and L satisfy a relationship: 3.5≤D/L≤5. For example, D and L satisfy a relationship: 4≤D/L≤7. For example, D and L satisfy a relationship: 4.5≤D/L≤6. For example, D and L satisfy a relationship: 3.5≤D/L≤8.

In some examples, as shown in FIG. 2, D satisfies: 4 mm≤D≤10 mm. For example, D satisfies: 5 mm≤D≤9.5 mm. For example, D satisfies: 6 mm≤D≤13.5 mm. For example, D satisfies: 5 mm≤D≤7.5 mm.

For example, as shown in FIG. 2, D satisfies: 8 mm≤D≤9.5 mm. For example, D satisfies: 7.5 mm≤D≤9 mm.

In some examples, as shown in FIG. 2, a portion of the light transmitting protection structure 200 with a thickness of H/2 in the first direction (e.g., the X direction) has a size D′ in the second direction (e.g., the Y direction), and D′ and L satisfy a relationship: 3.5≤D′/L≤12.5. For example, D′ and L satisfy a relationship: 3.5≤D′/L≤5.

By setting a relationship among the size of a light emitting unit in a direction parallel to the substrate, by setting the distance in the direction parallel to the substrate between the highest point and the lowest point of the first portion of the light transmitting protection structure and the size of the light transmitting protection structure in the direction parallel to the substrate, as well as by setting the size relationship in the direction parallel to the substrate between the light emitting unit and the position where the light transmitting protection structure has a thickness of half, the light pattern of the light emitted through the light transmitting protection structure from the light emitting unit can be modulated, it is beneficial for reducing the light-emitting intensity within ±50 degrees of the exiting light rays emitted by the light emitting unit after passing through the light transmitting protection structure. Thereby, it can reduce the difference in light-emitting intensity between the area directly above light emitting unit and the area between adjacent light emitting units, solve the problem of bright and dark stripes that may occur when the light-emitting structure is used for display and improve the uniformity of light emission of the optical structure so as to achieve a uniform picture display.

For example, as shown in FIG. 2, D′ and L satisfy a relationship: 3.7≤D′/L≤4.5. For example, D′ and L satisfy a relationship: 4≤D′/L≤4.8. For example, D′ and L satisfy a relationship: 3.5≤D′/L≤12.5.

In some examples, as shown in FIG. 2, the light emitting unit 100 includes an LED chip. For example, light emitting unit 100 may be an unpackaged LED chip. For example, the LED may be a sub-millimeter light-emitting diode (Mini LED) or a micro light-emitting diode (Micro LED). For example, each light emitting unit 100 may include a p electrode, a p-type semiconductor layer, an n electrode, an n-type semiconductor layer and a light emitting layer. Holes and electrons are injected into the n-type semiconductor layer and the p-type semiconductor layer from the n-type electrode and the p-type electrode, respectively, and recombine within the light emitting layer and manifest the release of energy in the form of photons, where the light-emitting wavelength is dependent on the forbidden bandwidth of a light emitting material.

For example, as shown in FIG. 2, the largest size of a light emitting unit 100 in a direction parallel to the substrate 01 is not greater than 3 mm. For example, the largest size of a light emitting unit 100 in a direction parallel to the substrate 01 is not greater than 500 micrometers (μm). For example, the largest size of a light emitting unit 100 in a direction parallel to the substrate 01 is not greater than 300 μm. For example, the largest size of a light emitting unit 100 in a direction parallel to the substrate 01 is not greater than 250 μm. For example, the largest size of a light emitting unit 100 in a direction parallel to the substrate 01 is not greater than 220 μm. For example, the largest size of a light emitting unit 100 in a direction parallel to the substrate 01 is not greater than 200 μm. For example, the largest size of a light emitting unit 100 in a direction parallel to the substrate 01 is not greater than 150 μm.

For example, as shown in FIG. 3, the outline shape of an orthographic projection of the light emitting unit 100 on the substrate 01 may be in the shape of a rectangle, and the maximum size of the light emitting unit 100 in the direction parallel to the substrate 01 may be a diagonal of the light emitting unit 100. Of course, this embodiment of the present disclosure is not limited thereto. For example, the outline shape of the orthographic projection of the light emitting unit 100 on the substrate 01 may be circular, and the maximum size of the light emitting unit 100 in the direction parallel to the substrate 01 may be a diameter of the light emitting unit 100. For example, the outline shape of the orthographic projection of the light emitting unit 100 on the substrate 01 may be ellipse, and the maximum size of the light emitting unit 100 in the direction parallel to the substrate 01 may be a length of a major axis of the light emitting unit 100. But not limited thereto, a side length of the planar shape of the light emitting unit 100 is also not greater than 3 mm.

In some examples, as shown in FIG. 2 and FIG. 3, a shape of an orthographic projection of the at least one light emitting unit 100 on the substrate 01 includes a rectangular, two adjacent sides of the rectangular extend in the second direction (e.g., the Y direction) and a third direction (e.g., the Z direction) respectively. For example, the orthographic projection of a light emitting unit 100 on the substrate 01 may be a rectangular, but embodiments of the present disclosure are not limited to this and the orthographic projection of a light emitting unit on the substrate may also be a square.

In some examples, as shown in FIG. 2 and FIG. 3, the ratio of the distance W1 in the second direction between the second position 202 and a first position 201 to the distance W2 in the third direction between the second position 202 and the first position 201 is in a range from 0.8 to 1.2. For example, the ratio of the distance W1 between the second position 202 and a first position 201 to the distance W2 between the second position 202 and the first position 201 is in a range from 0.9 to 1.1. For example, the distance W1 between the second position 202 and the first position 201 is equal to the distance W2 between the second position 202 and the first position 201, which is beneficial for the light transmitting protection structure to make basically the same secondary light pattern change on the light rays emitted from the light-emitting unit in the above-described two directions.

For example, when the orthographic projection of the light emitting unit 100 on the substrate 01 is a rectangular and the above-described W1 and W2 are set to be equal to each other, the light emitting unit has differences in light patterns in the long-side direction and the short-side direction of the rectangle, such differences in light patterns can be compensated for by controlling the pitches for arrangement of a plurality of light emitting units in the long side direction and the short side direction of the light emitting unit.

For example, as shown in FIG. 2 and FIG. 3, the difference between the thickness at the first position 201 which is located at one side of the second location 202 in the second direction and the thickness at the second position 202 is Hm1, the difference between the thickness at the first position 201 at one side of the second position 202 in the third direction and the thickness at the second position 202 is Hm2, and the ratio of Hm1 to Hm2 is in a range from 0.8 to 1.2. For example, the ratio of Hm1 to Hm2 is in a range from 0.9 to 1.1. For example, Hm1 is equal to Hm2.

For example, as shown in FIGS. 2 and 3, the orthographic projection of at least one light transmitting protection structure 200 on the substrate 01 is a circular. But not limited thereto, for example, the shape of the orthographic projection of each of at least one light transmitting protection structure on the substrate includes an elliptical. For example, the shape of the orthographic projection of the ring shaped first position 201 on the substrate 01 is the same as the shape of the orthographic projection of the light transmitting protection structure 200 on the substrate 01.

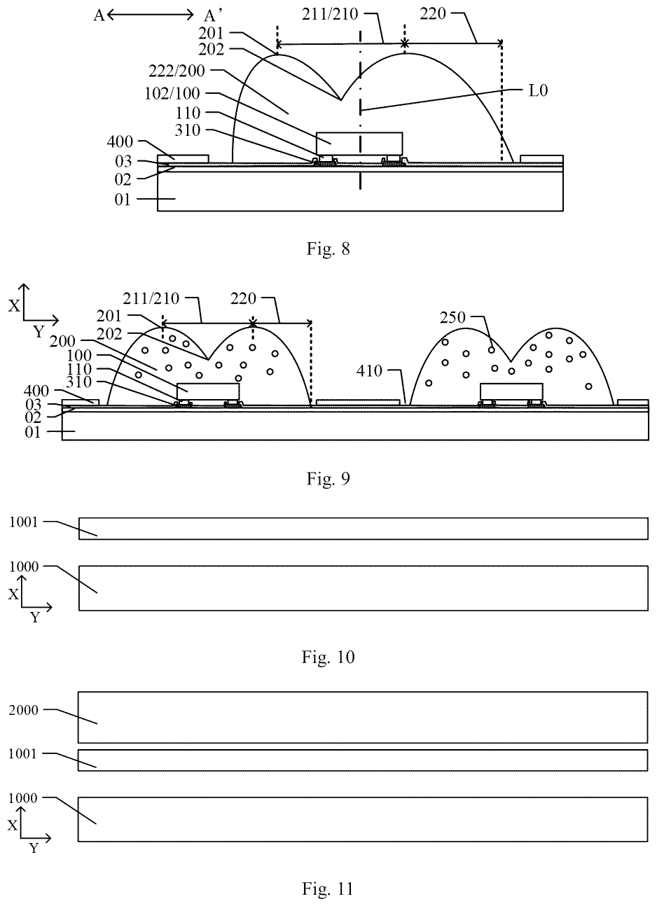

FIG. 7 is a planar structure of a light-emitting structure in another example according to an embodiment of the present disclosure. FIG. 8 is a partial cross-sectional structure diagram taken along the line AA′ shown in FIG. 7.

In some examples, as shown in FIG. 7 and FIG. 8, at least one light transmitting protection structure 200 includes a plurality of light transmitting protection structures 200, and each of at least some light emitting units 100 of a plurality of light emitting units 100 is wrapped by one light transmitting protection structure 200. For example, each of all the light emitting units 100 is wrapped by one light transmitting protection structure 200.

In some examples, as shown in FIG. 7, the substrate 01 includes a first area 011 and a second area 012 located on at least one side of the first area 011. For example, the first area 011 may be an area including the geometric center of the substrate 01. For example, the first area 011 may be a regular shape such as a rectangular or a circular, or may be an irregular shape. For example, the second area 012 is the area of the substrate 01 other than the first area 011. For example, the second area 012 surrounds the first area 011.

In some examples, as shown in FIG. 7, light emitting units 100 include a first light emitting unit 101 located in the first area 011 and a second light emitting unit 102 located in the second area 012, the plurality of light transmitting protection structures 200 include a first light transmitting protection structure 221 wrapping the first light emitting unit 101 and a second light transmitting protection structure 222 wrapping the second light emitting unit 102.

For example, as shown in FIG. 7, the orthographic projection of the first light transmitting protection structure 221 on the substrate 01 may have the same shape as the orthographic projection of the second light transmitting protection structure 222 on the substrate 01. But not limited thereto, the orthographic projection of the first light transmitting protection structure on the substrate may have a shape different from the shape of the orthographic projection of the second light transmitting protection structure on the substrate to change secondary light patterns in different areas.

For example, as shown in FIG. 7, the relative position relationship between the orthographic projection of the first light transmitting protection structure 221 on the substrate 01 and the orthographic projection of the first light emitting unit 101 on the substrate 01 may be the same as the relative position relationship between the orthographic projection of the second light transmitting protection structure 222 on the substrate 01 and the orthographic projection of the second light emitting unit 102 on the substrate 01.

In some examples, as shown in FIGS. 7 and 8, the second area 012 may be an area located at the edge of the substrate 01, the straight line passing through the light emitting center of the first light emitting unit 101 and perpendicular to the substrate 01 passes through the second position 202 of the first light transmitting protection structure 221, the orthographic projection of the second light emitting unit 102 on the substrate 01 has a second shape and the smallest distance between the second position 202 and the straight line passing through the light emitting center of the second light emitting unit 102 and perpendicular to the substrate 01 is greater than 0 and less than or equal to half of the size of the second shape, which is beneficial to improving the utilization ratio of light. For example, if the above-described second shape is a polygon, the size of the second shape is the length of a diagonal line or any side of the polygon; if the above-described second shape is a circle, the size of the second shape is the diameter of the circle; or if the above-described second shape is an ellipse, the size of the second shape is the major axis or minor axis of the ellipse.

For example, as shown in FIG. 7 and FIG. 8, the straight line LO that is through the light emitting center of the second light emitting unit 102 and perpendicular to the substrate 01 is at the side of the second position 202 of the second light transmitting protection structure 222 close to the first area 011, so that the light emitted from the light emitting units at the edge may deflect toward the center and improve the utilization ratio of light from the light emitting units in the area at the edge of the optical structure.

For example, as shown in FIG. 7, the relative position relationships between the second light emitting units 102 at different positions and the second positions 202 in the corresponding second light transmitting protection structures 222 may be different. For example, the second area 012 may include two parts of areas located on both sides of the first area 011 in the second direction and the second positions 202 of the second light transmitting protection structures 221 located in the two parts of areas are all closer to the first area 011 than the corresponding straight lines LO. For example, the second area 012 includes comer areas and side areas, wherein the comer areas may be areas near the four corners of the substrate 01 and the side areas may include areas near the straight sides of the substrate 01 extending in the Y direction and areas close to the straight sides of the substrate 01 extending in the Z direction. The relative position relationship between the second light emitting units 102 located in the corner areas and the second positions 202 in the corresponding second light transmitting protection structures 221 is different from the relative position relationship between the second light emitting units 102 located in the side areas and the second positions 202 in the corresponding second light transmitting protection structures 221. For example, the arrow in the Y direction points to the left, the arrow in the Z direction points upwards. Take the corner area at the upper left comer as an example, the center of a second light emitting unit 102 located in the corner area at the upper left corner is offset to the right and downward by a certain distance relative to the second position 202 of the second light transmitting protection structure 222, while the center of the second light emitting unit 102 located in the left side area is only offset to the right by a certain relative to the second position of the second light transmitting protection structure 222.

In some examples, as shown in FIG. 2, the light-emitting structure further includes a reflective layer 400, located on a side of the substrate 01 provided with the light emitting units 100. The reflective layer 400 includes a plurality of openings 410, the plurality of openings 410 are disposed in one-to-one correspondence with the plurality of light emitting units 100. A size of at least one opening 410 is D0, and D0 and D satisfy a relationship: 1.2≤D0/D≤1.5. For example, D0 and D satisfy a relationship: 1.32 ≤D0/D≤1.4. For example, D0 and D satisfy a relationship: 1.38≤D0/D≤1.45. For example, D0 and D satisfy a relationship: 1.25≤D0/D≤1.35. For example, the size of each of the plurality of openings 410 is D0.

For example, as shown in FIG. 2, there is no overlap between the orthographic projections of light emitting units 100 on the base substrate 01 and the orthographic projection of the reflective layer 400 on the base substrate 01. For example, there is no overlap between the orthographic projections of light transmitting protection structures 200 on the base substrate 01 and the orthographic projection of the reflective layer 400 on the base substrate 01. For example, each light transmitting protection structure 200 is located within the opening 410 in the reflective layer 400.

For example, as shown in FIG. 2, the reflective layer 400 may include a reflective sheet. FIG. 2 schematically shows a reflective sheet as the reflective layer 400 and the plurality of openings 410 included in the reflective layer 400 are all openings of the reflective sheet, and the size of the openings of the reflective sheet is larger than the maximum size of the light transmitting protection structure. But not limited thereto, the reflective layer may also include a white ink layer (not shown in the figures). Light transmitting protection structures overlap with the white ink layer, and the openings included in the white ink layer are used to expose pads.

In some examples, as shown in FIG. 2, a material of the light transmitting protection structures 200 includes organic silica gel, a refractive index of the light transmitting protection structures is in a range from 1.3 to 1.7 and a transmissivity of the light transmitting protection structure is greater than 80%. For example, the refractive index of the light transmitting protection structures 200 is in a range from 1.47 to 1.53. For example, the transmissivity of the light transmitting protection structures 200 is greater than 90%.

FIG. 9 is a partial structure diagram of a light-emitting structure in another example according to an embodiment of the present disclosure. The light-emitting structure shown in FIG. 9 is different from the light-emitting structure shown in FIG. 2 in that the light transmitting protection structures 200 includes different materials. The structures in the light-emitting structure shown in FIG. 9 other than the light transmitting protection structures and the light emitting units may have the same characteristics as the structures in the light-emitting structure shown in FIG. 2 other than its light transmitting protection structures and light emitting units and will not be described here repeatedly. The relationships in location and size between the light transmitting protection structures and the light emitting units shown in FIG. 9 may have the same characteristics as the relationships in location and size between the light transmitting protection structures and the light emitting units shown in FIG. 2 and will not be described here repeatedly.

In some examples, as shown in FIG. 9, an emission wavelength of the light emitted from the light emitting units 100 is in a range from 430 nanometers (nm) to 480 nanometers and the light transmitting protection structure 200 includes an inorganic light emitting material 250. For example, light emitting unit 100 includes a blue light emitting chip to emit blue light.

For example, the inorganic light emitting material 250 may be dispersed in the light transmitting protection structures 200 uniformly or may concentrate in the part of light transmitting protection structure 200 on the light emitting side.

For example, as shown FIG. 9, the inorganic light emitting material 250 is composed of a fluorescent material. The fluorescent material may be inorganic particles, organic particles, organic molecules or a combination thereof. Suitable inorganic particles include doped garnets (such as YAG:Ce and (Y, Gd)AG:Ce), aluminates (such as Sr2A114025: Eu and BAM:Eu), silicates (such as SrBaSiO: Eu), sulfides (such as ZnS:Ag, CaS:Eu and SrGa2S4:Eu), oxysulfidse, oxn-nitrides, phosphates, borates, and tungstates (such as CaWO4). These materials may be in the form of powder of conventional inorganic light emitting material or powder of a nanoparticle inorganic light emitting material. Another suitable type inorganic particles refers to a so-called quantum dot inorganic light emitting material made from semiconductor nanoparticles including: Si, Ge, CdS, CdSe, CdTe, ZnS, ZnSe, ZnTe, PbS, PbSe, PbTe, InN, InP, InAs, AlN, AlP, AlAs, GaN, GaP, GaAs and combinations thereof. Generally, the surface of each quantum dot is at least partially covered with organic molecules, thereby preventing agglomeration and improving the compatibility with binders. In some cases, the semiconductor quantum dots may consist of several layers of different materials in a core-shell structure. Suitable organic molecules include fluorescent dyes. A phosphor powder layer may include a mixture of different types of inorganic light emitting materials in a single layer or multiple layers, each layer contains one or more inorganic light emitting materials. Particles of the light emitting material in the phosphor powder layer may have different particle sizes (e.g., diameters) and may be separated.

Embodiments of the present disclosure are not limited to this, light emitting unit may also include a red light emitting chip and a green light emitting chip, in which case there may be no inorganic light emitting material disposed in light transmitting protection structures.

There may be many processes used to fabricate the light transmitting protection structures in embodiments of the present disclosure, for example, any one of photolithography, printing, inkjet printing, pad printing, embossing, stamping and coating.

For example, the process of forming the light transmitting protection structure 200 shown in FIG. 2 may specifically include the following steps.

In step S1, a light transmitting protection structure layer is formed using an adhesive dispensing apparatus.

For example, the adhesive dispensing apparatus includes at least one nozzle. For example, the diameter of the nozzle may be in a range from 0.1 mm to 0.3 mm. For example, in the case where the temperature of the equipment for forming the light transmitting protection structure layer is 80° C., the nozzle moves at the speed of 8 mm/s, sets the dispensing trajectory in the manner of drawing a circle with three points and draws three circles in total to dispense the light transmitting protection structure layer, such as in the shape of concave protective glue. For example, the diameters of the circles drawn three times can be the same, for example, the diameters may all be in a range from 2 mm to 3 mm, for example, 2.55 mm.

In step S2, after adhesive dispensing, the light transmitting protection structure layer is settled statically for 1 hour in an environment at, for example, a temperature is in a range from 10° C. to 30° C., then settled statically for 1 hour when the apparatus temperature is 60° C., and finally placed into a heating furnace at 170° C. to cure the protection adhesive, so that a light transmitting protection structure 200 with recessed portion may be formed.

For example, a CCD camera may be used to take pictures of the backlight screen of the backlight source including the light-emitting structure, and calculations may be carried out on the photographed pictures. For example, the CCD camera captures the brightnesses of two adjacent light emitting units and the brightnesses of the two light emitting units are calculated to be Lₘₐₓ and Lₘᵢₙ respectively. If the ratio of the brightnesses difference between the two light emitting units to Lₘₐₓ, i.e., (Lₘₐₓ−Lₘᵢₙ)/Lₘₐₓ<2%, human eyes can basically not distinguish the obvious brightness and darkness differences of the backlight source. If the ratio of the brightnesses difference between the two light emitting units to Lₘₐₓ, i.e., (Lₘₐₓ−Lₘᵢₙ)/Lₘₐₓ, is in a range from 5% to 6%, obvious lamp shadows can be seen by human eyes. If the ratio of the brightnesses difference between the two light emitting units to Lₘₐₓ, i.e., (Lₘₐₓ−Lₘᵢₙ)/Lₘₐₓ, is greater than 6%, serious lamp shadows may occur.

FIG. 10 is a partial cross-sectional structure diagram of a backlight source according to another embodiment of the present disclosure. As shown in FIG. 10, the backlight source includes the light-emitting structure 1000 in any example described above.

For example, as shown in FIG. 10, the backlight source may further include a light diffusing structure 1001 located on the light emitting side of the light-emitting structure 1000. For example, the light diffusing structure 1001 may include at least one light diffusing layer. For example, the light diffusing structure 1001 may include a first light diffusing layer and a second light diffusing layer, one of the first light diffusing layer may be a particulate diffusing plate, and the other of the first light diffusion layer and the second light diffusion layer may be a diffusing film with microstructures on the surface.

For example, the backlight source may further include film layers (not shown) such as a diffusion layer, a brightness enhancing film and a color conversion layer, the diffusion layer, the brightness enhancing film and the color conversion layer and other film layers are all located on the side of light diffusing structure away from the light-emitting structure. For example, the brightness enhancing film may be a prism layer that functions to converge light and improve the brightness of the light emitted at the positive viewing angle. For example, the color conversion layer may convert the light from light emitting units from one color to another color. For example, when light emitting units emit blue light, the color conversion layer may include a phosphor layer that converts the blue light into white light. For example, the phosphor layer includes quantum dots that convert the blue light into red light and green light. For example, in addition to the phosphor layer, the color conversion layer may include a partially reflective layer. For example, the partially reflective layer (also referred to as a dichroic layer or a dichroic filter layer) may reflect all of the red light and the green light and reflect the blue light partially. In a case where a color conversion layer is disposed in the backlight source, the inorganic light emitting material 250 shown in FIG. 9 may not be provided in the light transmitting protection structure. For example, in a case where the inorganic light emitting materials 250 shown in FIG. 9 is set in the light transmitting protection structure, the color conversion layer may not be provided in the backlight source.

FIG. 11 is a partial cross-sectional structure diagram of a display apparatus according to another embodiment of the present disclosure. As shown in FIG. 11, the display apparatus includes the light-emitting structure 1000 in any example described above. For example, as shown in FIG. 11, the display apparatus includes the backlight source shown in FIG. 10.

For example, as shown in FIG. 11, the display apparatus further includes a display panel 2000 stacked on the light-emitting structure 1000. For example, the display panel 2000 is located at the light emitting side of the light-emitting structure 1000, and the light-emitting structure 1000 is configured to provide back light to the display panel 2000. For example, the display panel 2000 may be a liquid crystal display panel. The liquid crystal display panel may include an array substrate (not shown), an opposing substrate (not shown), and a liquid crystal layer (not shown) located between the array substrate and the opposing substrate.

For example, one side of the array substrate facing toward the opposing substrate may include a plurality of gate lines extending in one direction and a plurality of data lines extending in another direction. The plurality of gate lines and the plurality of data lines intersect to define a plurality of pixel units arranged in an array. The plurality of pixel units may be arranged as a pixel array. Each pixel unit may include a pixel electrode and a thin-film transistor. The gate line is connected to a gate of the thin-film transistor to control on or off of the thin-film transistor. The pixel electrode is connected to one of a source electrode and a drain electrode of the thin-film transistor. The data line is connected to the other of the source electrode and the drain electrode of the thin-film transistor. The data line inputs a voltage signal required the display image to the pixel electrode through the thin-film transistor to achieve the display of the arrayed substrate.

For example, the opposing substrate may be a color film substrate, and a color film layer corresponding to the pixel units and a black matrix covering the structures such as a gate line and a data line that are located in a non-display area may be provided on a side of the color film substrate facing toward the array substrate. For example, a common electrode disposed opposite the pixel electrode may also be provided on the side of the color film substrate facing toward the array substrate. The common electrode is configured to apply a common voltage to generate an electric field with the pixel electrode to drive liquid crystal molecules in the liquid crystal layer to deflect. The liquid crystal molecules are deflected to change the transmissivity of the liquid crystal layer, thereby realizing the display of a desired grayscale image. For example, both the common electrode and the pixel electrode may be located on the array substrate.

The following statements should be noted:
(1) The accompanying drawings related to the embodiment(s) of the present disclosure involve only the structure(s) in connection with the embodiment(s) of the present disclosure, and other structure(s) can be referred to common design(s).
(2) In case of no conflict, features in one embodiment or in different embodiments of the present disclosure can be combined.

The foregoing is merely exemplary embodiments of the disclosure, but is not used to limit the protection scope of the disclosure. The protection scope of the disclosure shall be defined by the attached claims.

1. : A light-emitting structure, comprising:
a substrate;
a plurality of light emitting units, located on the substrate; and
at least one light transmitting protection structure, configured to wrap at least one light emitting unit,
wherein each light transmitting protection structure wraps one light emitting unit, an outer surface of the light transmitting protection structure comprises a first portion and a second portion surrounding the first portion, a boundary position between the first portion and the second portion comprises a first position that is farthest from the substrate in the light transmitting protection structure, the first portion comprises a recessed portion bent to a side close to the light emitting unit, the recessed portion comprises a second position that is closest to the substrate in the first portion, a thickness of the light transmitting protection structure at the first position is H, a maximum thickness of the light emitting unit in a first direction perpendicular to the substrate is h, and H and h satisfy a relationship: 1<H/h<17.

2. he light-emitting structure according to claim 1, wherein, in a second direction parallel to the substrate, a distance between the first position and the second position is W, a size of the light emitting unit in the second direction is L, a largest size of the light transmitting protection structure in the second direction is D, and W, L and D satisfy a relationship: L/2 <W<D/2.

3. The light-emitting structure according to claim 1, wherein an orthographic projection of the second position on the substrate is located within an orthographic projection of the light emitting unit on the substrate.

4. The light-emitting structure according to claim 3, wherein the orthographic projection of the light emitting unit on the substrate has a first shape, a smallest distance between the second position and a straight line passing through a light emitting center of the light emitting unit and perpendicular to the substrate is greater than or equal to 0, and less than or equal to half of a size of the first shape.

5. The light-emitting structure according to claim 1, wherein a difference between H and a thickness of the light transmitting protection structure at the second position is Hm, and Hm/H<0.5.

6. The light-emitting structure according to claim 2, wherein a portion of the light transmitting protection structure with a thickness of H/2 has a size D′ in the second direction, and D′ and L satisfy a relationship: 3.5≤D′/L≤12.5.

7. The light-emitting structure according to claim 2, wherein D and L satisfy a relationship: 3≤D/L≤13.5.

8. The light-emitting structure according to claim 1, wherein the light emitting unit comprises a light emitting diode chip and the outer surface of the light transmitting protection structure covering the light emitting unit comprises a free-form curved surface.

9. The light-emitting structure according to claim 8, wherein the outer surface of the light transmitting protection structure from the second position to the first position comprises at least a section of a curved surface and/or a section of a planar surface.

10. The light-emitting structure according to claim 1, wherein the at least one light transmitting protection structure comprises a plurality of light transmitting protection structures, and each of at least some light emitting units of the plurality of light emitting units is wrapped by one light transmitting protection structure; and
the substrate comprises a first area and a second area located on at least one side of the first area, the at least some light emitting units comprise a first light emitting unit located in the first area and a second light emitting unit located in the second area, the plurality of light transmitting protection structures comprise a first light transmitting protection structure wrapping the first light emitting unit and a second light transmitting protection structure wrapping the second light emitting unit, a straight line passing through a light emitting center of the first light emitting unit and perpendicular to the substrate passes through the second position of the first light transmitting protection structure, an orthographic projection of the second light emitting unit on the substrate has a second shape and a smallest distance between the second position and a straight line passing through a light emitting center of the second light emitting unit and perpendicular to the substrate is greater than 0, and less than or equal to half of a size of the second shape.

11. The light-emitting structure according to claim 2, wherein a shape of an orthographic projection of the at least one light emitting unit on the substrate comprises a rectangular, two adjacent sides of the rectangular extend in the second direction and a third direction respectively; and
the light transmitting protection structure comprises one second position and a plurality of first positions, and the plurality of first positions surround the second position, a ratio of a distance between the second position and the first position in the second direction to a distance between the second position and the first position in the third direction is in a range from 0.8 to 1.2, and a ratio of distances between different first positions and the substrate is in a range from 0.8 to 1.2.

12. The light-emitting structure according to claim 11, wherein distances between the plurality of first positions and the substrate are all the same.

13. The light-emitting structure according to claim 11, wherein the plurality of first locations are connected in a clockwise direction to form a circular shape or an elliptical shape.

14. The light-emitting structure according to claim 5, wherein Hm satisfies: 0 mm<Hm≤1.2 mm.

15. The light-emitting structure according to claim 1, wherein H satisfies: 0.5 mm≤H≤2 mm.

16. The light-emitting structure according to claim 2, wherein D satisfies: 4 mm≤D≤10 mm.

17. The light-emitting structure according to claim 2, further comprising:
a reflective layer, located on a side of the substrate provided with the plurality of light emitting units,
wherein the reflective layer comprises a plurality of openings, the plurality of openings are disposed in one-to-one correspondence with the plurality of light emitting units, a size of at least one opening is D0, and D0 and D satisfy a relationship: 1.2≤D0/D≤1.5.

18. The light-emitting structure according to claim 1, wherein a material of the light transmitting protection structure comprises organic silica gel, a refractive index of the light transmitting protection structure is in a range from 1.3 to 1.7 and a transmissivity of the light transmitting protection structure is greater than 80%,
an emission wavelength of the light emitting unit is 430 nanometers to 480 nanometers and the light transmitting protection structure comprises an inorganic light emitting material.

19. (canceled)

20. A backlight source, comprising the light-emitting structure according to claim 1.

21. A display apparatus, comprising the light-emitting structure according to claim 1.
